(19) United States
(12) Patent Application Publication
(10) Pub. No.: US 2014/0240278 A1
(43) Pub. Date: Aug. 28, 2014

(54) OPERATIONAL AMPLIFIER AND TOUCH SENSING APPARATUS INCLUDING THE SAME

(71) Applicants: Ki-Duk Kim, HWASEONG-SI (KR); Junchul Park, BUK-GU (KR); San-Ho Byun, BUCHEON-SI (KR); Minchul Lee, YONGIN-SI (KR); Ji-Sung Jung, YONGIN-SI (KR); Yoonkyung Choi, GANGNAM-GU (KR)

(72) Inventors: Ki-Duk Kim, HWASEONG-SI (KR); Junchul Park, BUK-GU (KR); San-Ho Byun, BUCHEON-SI (KR); Minchul Lee, YONGIN-SI (KR); Ji-Sung Jung, YONGIN-SI (KR); Yoonkyung Choi, GANGNAM-GU (KR)

(21) Appl. No.: 14/135,115

(22) Filed: Dec. 19, 2013

(30) Foreign Application Priority Data
Feb. 25, 2013 (KR) 10-2013-0019824

(51) Int. Cl. G06F 3/044; H03F 1/14

(52) U.S. Cl. CPC G06F 3/044; H03F 1/14
USPC 345/174; 330/252

(57) ABSTRACT

A touch sensing apparatus is provided. The touch sensing apparatus includes a touch panel and a touch sensor configured to control the touch panel and sense a touch through the touch panel. The touch sensor includes a plurality of sensing units connected to the touch panel through a plurality of sensing lines respectively. Each of the plurality of sensing units includes at least an operational amplifier whose polarity varies in response to a clock signal.

### CROSS-REFERENCE TO RELATED APPLICATIONS

This U.S. non-provisional patent application claims priority under 35 U.S.C. §119 to Korean Patent Application No. 10-2013-0019824, filed on Feb. 25, 2013, in the Korean Intellectual Property Office, the disclosure of which is incorporated by reference in its entirety.

### TECHNICAL FIELD

The present disclosure relates to a semiconductor device, and more particularly, to an operational amplifier, and a touch sensing apparatus including the same.

### DISCUSSION OF THE RELATED ART

Touch sensing apparatuses are configured to sense external touch. Touch sensing apparatuses are being used for various devices such as smart phones, tablet PCs, user's equipment, or the like. Such a touch sensing apparatus may include a touch panel that may output a signal in response to external touch and a touch sensor for determining a location where the touch occurs based on the signal outputted from the touch panel.

The touch sensing apparatus may either be a capacitive touch sensing apparatus, a resistive touch sensing apparatus, or a transparent electrode touch sensing apparatus. The capacitive touch sensing apparatus may be equipped to recognize multiple simultaneous touches at different locations.

However, internal noises and external noises may be generated in the touch sensing apparatus. The noises may affect the performance of touch recognition and touched position determination through the touch sensing apparatus.

### SUMMARY

According to an embodiment of the present inventive concept, a touch sensing apparatus is provided. The touch sensing apparatus includes a touch panel, a touch sensor configured to control the touch panel and sense a touch through the touch panel. The touch sensor includes a plurality of sensing units connected to the touch panel through a plurality of sensing lines respectively. Each of the plurality of sensing units includes at least operational amplifier whose polarity varies in response to a clock signal.

In an embodiment of the present inventive concept, the operational amplifier may include a differential input unit, an amplification unit, and an output unit. The differential input unit may be configured to detect a value of a signal level at a first input node minus a signal level at a second input node in response to a first edge of the clock signal to output a first detection signal. The differential input unit may be configured to detect a value of the signal level at the second input node minus the signal level at the first input node in response to a second edge of the clock signal to output a second detection signal. The amplification unit may be configured to amplify the first detection signal in response to the first edge of the clock signal to output a first amplification signal. The amplification unit may be configured to amplify the second detection signal in response to the second edge of the clock signal to output a second amplification signal. The output unit may be configured to output the first amplification signal in response to the first edge of the clock signal. The output unit may be configured to output the second amplification signal in response to the second edge of the clock signal.

In an embodiment of the present inventive concept, each of the plurality of sensing units may include a charge amplifier, a demodulator, a low pass filter, a gain amplifier, and an analog-to-digital converter. The charge amplifier may be configured to convert a current signal received through one of the plurality of sensing lines into a voltage signal to output the converted voltage signal. The demodulator may be configured to demodulate the output signal of the charge amplifier. The low pass filter may be configured to filter the output signal of the demodulator. The gain amplifier may be configured to amplify the output signal of the low pass filter. The analog-to-digital converter may be configured to sample the output signal of the gain amplifier in response to a sampling clock signal. The operational amplifier may be disposed in at least one of the modulator, the low pass filter, and the gain amplifier.

In an embodiment of the present inventive concept, the demodulator may include a first operational amplifier, a second operational amplifier, and a multiplexer. The first operational amplifier may be configured to operate in response to a first clock signal. The first operational amplifier may form a voltage follower configured to transmit the output signal of the charge amplifier. The second operational amplifier may be configured to operate in response to a second clock signal. The second operational amplifier forms an inverter configured to invert the output signal of the charge amplifier to output the inverted signal. The multiplexer may be configured to select one of the outputs of the first operational amplifier and the second operational amplifier in response to a demodulating clock signal to output the selected output.

In an embodiment of the present inventive concept, the touch sensor may further include a driving circuit connected to the touch panel through a plurality of driving lines. The driving circuit is configured to output a pulse signal including a series of pulses to each of the plurality of driving lines.

In an embodiment of the present inventive concept, the demodulating clock signal may have the same period and duty ratio as those of the pulse signal.

In an embodiment of the present inventive concept, the duty ratios of the first clock signal and the second clock signal may be substantially same as the period of the demodulating clock signal. The periods and pulse widths of the first clock signals and the second clock signals may have substantially twice as great as the demodulating clock signal. The first clock signal and the second clock signal are synchronized with the demodulating clock signal.

In an embodiment of the present inventive concept, the demodulating clock signal may have the first edge when the first clock signal is maintained at a predetermined level without being transited. The demodulating clock signal may have the second edge when the second clock signal is maintained at a predetermined level without being transited.

In an embodiment of the present inventive concept, the demodulating clock signal may have the first edge when a first time elapses after the first clock signal is transited. The demodulating clock signal may have the second edge when a second time elapses after the second clock signal is transited.

In an embodiment of the present inventive concept, the low pass filter may further include a first low pass filter and a second low pass filter. The first low pass filter may be configured to filter the output signal of the multiplexer. The first low pass filter may include a third operational amplifier configured to operate in response to a third clock signal. The second low pass filter may be configured to filter the output signal of the first low pass filter. The second low pass filter may include a fourth operational amplifier configured to operate in response to a fourth clock signal.

In an embodiment of the present inventive concept, the fourth clock signal may be synchronized with the sampling clock signal.

In an embodiment of the present inventive concept, the analog-to-digital converter may be configured to perform the sampling when a predetermined time elapses after the fourth clock signal is transited.

In an embodiment of the present inventive concept, the gain amplifier may include a fifth operational amplifier, an input resistor, and an feedback resistor. The fifth operational amplifier may be configured to amplify the output signal of the low pass filter according to a resistance ratio of the input resistor to feedback resistor. The fifth operational amplifier may be configured to operate in response to a fifth clock signal. The analog-to-digital converter may be configured to perform the sampling when a predetermined time elapses after the fifth clock signal is transited.

In an embodiment of the present inventive concept, the charge amplifier may include an operational amplifier connected to one of the plurality of sensing lines, a feedback resistor, and a feedback capacitor. Each of the plurality of sensing units further includes a saturation detector configured to detect whether the charge amplifier is saturated to output a saturation flag signal.

In an embodiment of the present inventive concept, each of the plurality of sensing units may further include a capacitance controller. The capacitance controller may be configured to adjust a capacitance of the feedback capacitor in response to the saturation flag signal.

In an embodiment of the present inventive concept, the touch sensing apparatuses may further include a capacitance controller. The capacitance controller may be configured to adjust capacitances of feedback capacitors of the charge amplifiers of the plurality of sensing units in response to the saturation flag signal.

In an embodiment of the present inventive concept, each of the plurality of sensing units may further include a noise detector. The noise detector may be configured to detect a noise from the output signal of the charge amplifier to output a noise flag signal.

In an embodiment of the present inventive concept, a capacitance of the feedback capacitor of the charge amplifier may be configured to adjust in response to the saturation flag signal and the noise flag signal.

According to an embodiment of the present inventive concept, an operational amplifier is provided. The operational amplifier includes a differential input unit, an amplification unit, and an output unit. The differential input unit is configured to detect a value of a signal level at a first input node minus a signal level at a second input node in response to a first edge of a clock signal to output a first detection signal. The differential input unit is configured to detect a value of the signal level at the second input node minus the signal level at the first input node in response to a second edge of the clock signal to output a second detection signal. The amplification unit is configured to amplify the first detection signal in response to the first edge of the clock signal to output a first amplification signal. The amplification unit is configured to amplify the second detection signal in response to the second edge of the clock signal to output a second amplification signal. The output unit is configured to output the first amplification signal in response to the first edge of the clock signal. The output unit is configured to output the second amplification signal in response to the second edge of the clock signal.

According to an embodiment of the present inventive concept, a touch sensing apparatus is provided. The touch sensing apparatus includes a touch panel and a touch sensor configured to control the touch panel and sense a touch through the touch panel. The touch sensor includes a plurality of sensing units connected to the touch panel through a plurality of sensing lines respectively. Each of the plurality of sensing units includes a charge amplifier, a demodulator, a low pass filter, a gain amplifier, an analog-to-digital converter, a saturation detector, and a controller. The charge amplifier is configured to convert a current signal received through one of the plurality of sensing lines into a voltage signal to output the converted voltage signal. The demodulator is configured to demodulate the output signal of the charge amplifier. The low pass filter is configured to filter the output signal of the demodulator. The gain amplifier is configured to amplify the output signal of the low pass filter. The analog-to-digital converter is configured to sample the output signal of the gain amplifier in response to a sampling clock signal. The saturation detector is configured to receive the output signal of the charge amplifier and detect whether the charge amplifier is saturated to output a saturation flag signal. The controller is configured to adjust an amplification factor of the charge amplifier in response to the saturation flag signal.

In an embodiment of the present inventive concept, the controller may include a capacitance controller configured to adjust a capacitance of the feedback capacitor in the charge amplifier.

In an embodiment of the present inventive concept, the charge amplifier may include an operational amplifier and a noise detector. The operational amplifier may be configured to receive the output signal received through one of the plurality of sensing lines. The noise detector may be configured to receive the output signal of the charge amplifier and detect a noise from the output signal of the charge amplifier to output a noise flag signal.

According to an embodiment of the present inventive concept, a touch sensor for controlling a touch panel is provided. The touch sensor includes a driving circuit, a sensing circuit, a control and processing circuit, and a capacitance controller. The driving circuit is configured to output a pulse signal to each of a plurality of driving lines connected to the touch panel. The sensing circuit is configured to sense a signal received from a plurality of sensing lines connected to the touch panel. The control and processing circuit is configured to control the driving circuit and the sensing circuit, and determine whether a touch on the touch panel occurs. The sensing circuit includes a plurality of sensing units connected to the touch panel through a plurality of sensing lines, respectively. Each of the plurality of sensing unit includes a charge amplifier. The charge amplifier is configured to convert a current signal received through each of the plurality of sensing lines into a voltage signal to output the converted voltage signal. The capacitance controller is configured to adjust a capacitance of the feedback capacitor in the charge amplifier.

In an embodiment of the present inventive concept, the capacitance controller may be located in the sensing circuit or in the control and processing unit.

In an embodiment of the present inventive concept, the touch sensor may include a saturation detector configured to receive the output signal of the charge amplifier and detect whether the charge amplifier is saturated.

### BRIEF DESCRIPTION OF THE DRAWINGS

The accompanying drawings are included to provide a further understanding of the inventive concept. The drawings illustrate exemplary embodiments of the inventive concept and, together with the description, serve to explain principles of the inventive concept. In the drawings:

FIG. 1 is a block diagram of a touch sensing apparatus according to an embodiment of the inventive concept;

FIG. 2 is a view of a touch panel according to an embodiment of the inventive concept;

FIG. 3 is a block diagram of a touch sensor according to an embodiment of the inventive concept;

FIG. 4 is a block diagram of a driving circuit according to an embodiment of the inventive concept;

FIG. 5 is a block diagram of a sensing circuit according to an embodiment of the inventive concept;

FIG. 6 is a detailed view illustrating one sensing unit of sensing units of

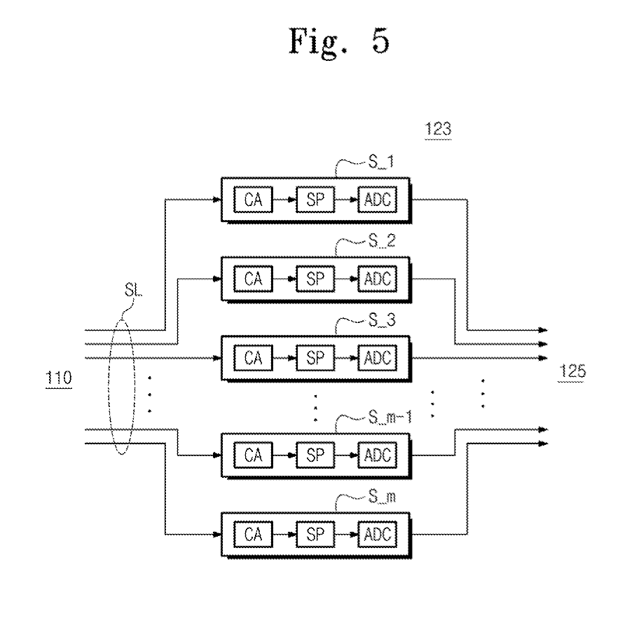

FIG. 5;

FIG. 7 is an equivalent circuit diagram for explaining an operation of the touch panel according to an embodiment of the inventive concept;

FIG. 8 is a view illustrating shapes of signal and noise outputted through each of the elements in an signal processor;

FIG. 9 is a graph illustrating internal noises;

FIG. 10 is a circuit diagram of an operational amplifier according to an embodiment of the inventive concept;

FIG. 11 is a circuit diagram of a demodulator according to an embodiment of the inventive concept;

FIG. 12 is a circuit diagram of a low pass filter according to an embodiment of the inventive concept;

FIG. 13 is a circuit diagram of the gain amplifier according to an embodiment of the present invention;

FIG. 14A is a timing diagram illustrating clock signals supplied into the demodulator and the low pass filter;

FIG. 14B is a timing diagram illustrating clock signals supplied into a low pass filter, a gain amplifier, and an analog-to-digital converter;

FIG. 15A is a graph illustrating a frequency response of a 1/f noise generated in each element of the signal processor;

FIG. 15B is a graph illustrating a frequency response of a 1/f noise varying by a chopping operation for changing a polarity in operational amplifiers of the signal processor;

FIG. 16 is a view of a charge amplifier according to an embodiment of the inventive concept;

FIG. 17 is a flowchart illustrating a process of operating the charge amplifier of FIG. 16;

FIG. 18 is a view of a charge amplifier according to an embodiment of the inventive concept;

FIG. 19 is a flowchart illustrating a process of operating the charge amplifier of FIG. 18;

FIG. 20 is a block diagram of a touch sensor according to an embodiment of the inventive concept;

FIG. 21 is a block diagram of a touch sensor according to an embodiment of the inventive concept; and

FIG. 22 is a block diagram of a mobile device according to an embodiment of the inventive concept.

### DETAILED DESCRIPTION OF THE EMBODIMENTS

Exemplary embodiments of the inventive concept will be described with reference to the accompanying drawings. However, the inventive concept may be embodied in different forms and should not be construed as limited to the embodiments set forth herein. In the drawings, the thickness of layers and regions may be exaggerated for clarity.

As used herein, the singular forms, “a”, “an” and “the” are intended to include both the singular and the plural forms, unless otherwise indicated herein or clearly contradicted by context.

Exemplary embodiment of the present inventive concept will be described here with reference to perspective views, cross-sectional views, and/or plan views. Thus, the profile of an exemplary view may be modified according to manufacturing techniques and/or allowances. The embodiments of the inventive concept are not intended to limit the scope of the present invention but are intended to cover all changes and modifications that can be caused due to a change in manufacturing process. Thus, regions shown in the drawings may be illustrated in schematic form and the shapes of the regions may be presented simply by way of illustration.

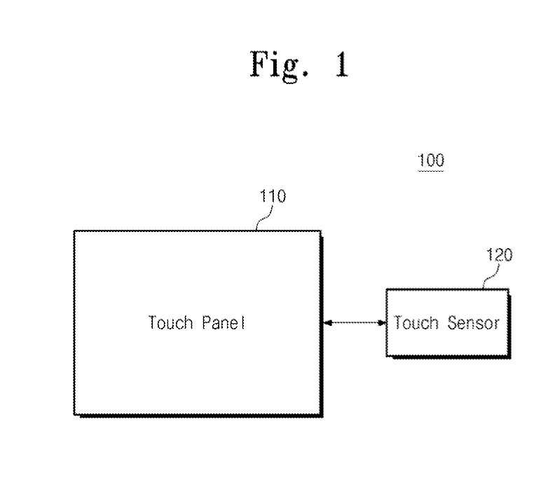

FIG. 1 is a block diagram of a touch sensing apparatus 100 according to an embodiment of the inventive concept. Referring to FIG. 1, the touch sensing apparatus 100 may include a touch panel 110 and a touch sensor 120.

The touch panel 110 is configured to output a signal varying in response to user's touch.

The touch sensor 120 is configured to control the touch panel 110 to sense the user's touch according to a variation of a signal outputted from the touch panel 110.

For example, the touch sensing apparatus 100 may include a capacitive touch sensing apparatus. However, the touch sensing apparatus 100 is not limited to the capacitive touch sensing apparatus. The touch sensing apparatus 100 may include a transparent electrode sensing apparatus or a resistive touch sensing apparatus.

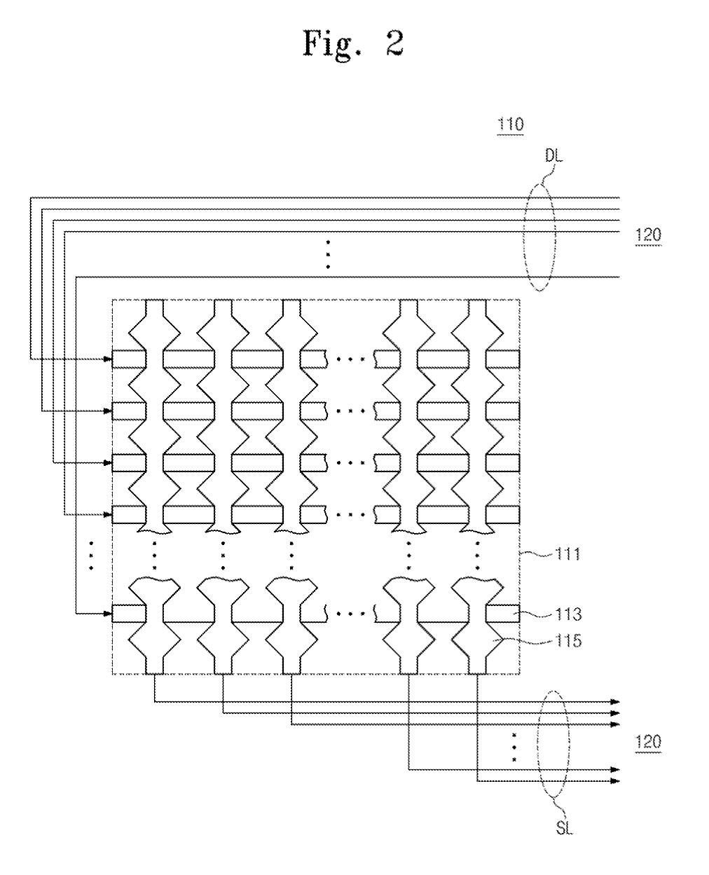

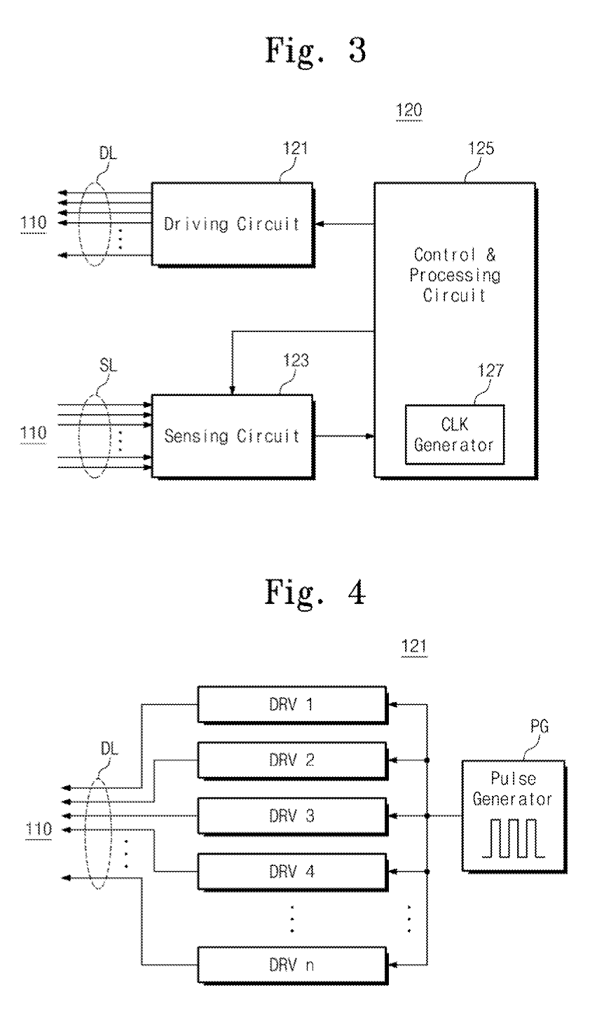

FIG. 2 is a view of the touch panel 110 according to an embodiment of the inventive concept. Referring to FIGS. 1 and 2, the touch panel 110 may include first conductive lines 113 and second conductive lines 115 which are arranged in a touch area 111.

The first conductive lines 113 may be arranged in parallel to a transverse axis direction in the touch area 111. The second conductive lines 115 may be arranged in parallel to a longitudinal axis direction in the touch area 111. The second conductive lines 115 may be disposed on the first conductive lines 113. The first conductive lines 113 and second conductive lines 115 may be electrically insulated from each other.

The second conductive lines 115 may have a specific pattern. For example, as shown in FIG. 2, the second conductive lines 115 may have a pattern in which lozenges are repeatedly arranged. However, the pattern of the second conductive lines 115 is not limited thereto

The first conductive lines 113 may be connected to a plurality of driving lines DL, respectively. The second conductive lines 115 may be connected to a plurality of sensing lines SL, respectively. The plurality of driving lines DL and the plurality of sensing lines SL may be connected to the touch sensor 120.

FIG. 3 is a block diagram of the touch sensor 120 according to an embodiment of the inventive concept. Referring to FIGS. 1 and 3, the touch sensor 120 may include a driving circuit 121, a sensing circuit 123, and a control and processing circuit 125.

The driving circuit 121 may be connected to the plurality of driving lines DL. The driving circuit 121 may be configured to apply a voltage signal into the plurality of driving lines DL according to the control signal from the control and processing circuit 125.

The sensing circuit 123 may be connected to the plurality of sensing lines SL. The sensing circuit 123 may be configured to sense a signal transmitted through the sensing lines SL according to the control signal from the control and processing circuit 125. The sensing circuit 123 may convert the sensed signal into a digital signal. The digital signal may be transmitted to the control and processing circuit 125.

The control and processing circuit 125 may be configured to control the driving circuit 121 and the sensing circuit 123. The control and processing circuit 125 may response to the digital signal received from the sensing circuit 123 to determine whether the user's touch occurs on the touch panel 110, or where the user′ touch occurs on the touch panel 110.

The control and processing circuit 125 may include a clock generator 127. The clock generator 127 is configured to generate a clock signal. The clock generator 127 may generate at least two clock signals whose periods or duty ratios different from each other. The clock signals generated by the clock generator 127 may be transmitted into the driving circuit 121 or the sensing circuit 123.

FIG. 4 is a block diagram of the driving circuit 121 according to an embodiment of the inventive concept. Referring to FIGS. 3 and 4, the driving circuit 121 includes a pulse generator PG and a plurality of driving units DRV1 to DRVn.

The pulse generator PG is configured to output a pulse signal including a series of pulses. For example, the pulse generator PG may autonomously output a pulse signal or output a pulse signal in response to the clock signal generated by the clock generator 127.

The plurality of driving units DRV1 to DRVn may be connected to the plurality of driving lines DL, respectively. The plurality of driving units DRV1 to DRVn is configured to receive the pulse signals outputted from the pulse generator PG and transmit the received pulse signals into the driving lines DL. For example, the plurality of driving units DRV1 to DRVn may output pulse signals in different times from each other into the driving lines DL. For example, when the first driving unit DRV1 outputs a pulse signal, each of the remaining driving units DRV2 to DRVn may not output a pulse signal. When the second driving unit DRV2 outputs a pulse signal, each of the remaining driving units DRV1 and DRV3 to DRVn may not output a pulse signal. The plurality of driving units DRV1 to DRVn may successively output the pulse signals in a scanning manner.

FIG. 5 is a block diagram of the sensing circuit 123 according to an embodiment of the inventive concept.

Referring to FIGS. 3 and 5, the sensing circuit 123 may include a plurality of sensing units S_1 to S_m.

Each of the plurality of sensing units S_1 to S_m may include a charge amplifier CA, a signal processor SP, and an analog-to-digital converter ADC.

The charge amplifier CA is configured to convert a signal received through the sensing lines SL into a voltage signal. The signal received through the sensing lines SL may be a current signal.

The signal processor SP is configured to process the output signal of the charge amplifier CA. For example, the signal processor SP may demodulate and filter the output signal of the charge amplifier CA. The signal processor SP may convert the output signal of the charge amplifier CA into a direct current (DC) signal.

The analog-to-digital converter ADC may convert an output signal of the signal processor SP into a digital signal. The output digital signal of the analog-to-digital converter ADC may be transmitted into the control and processing circuit 125.

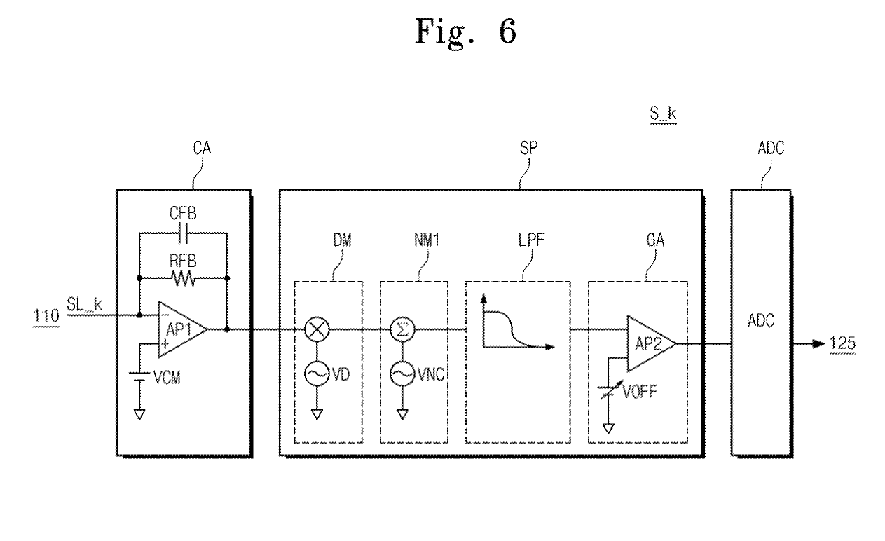

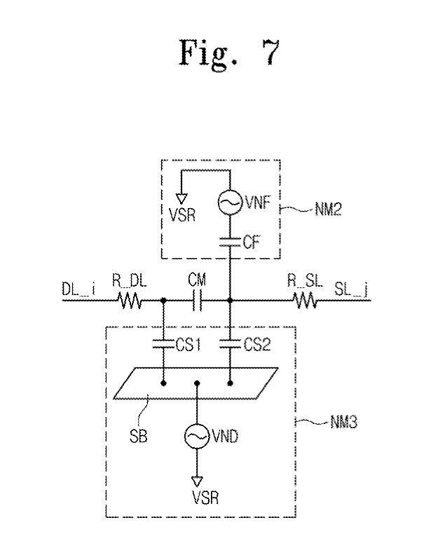

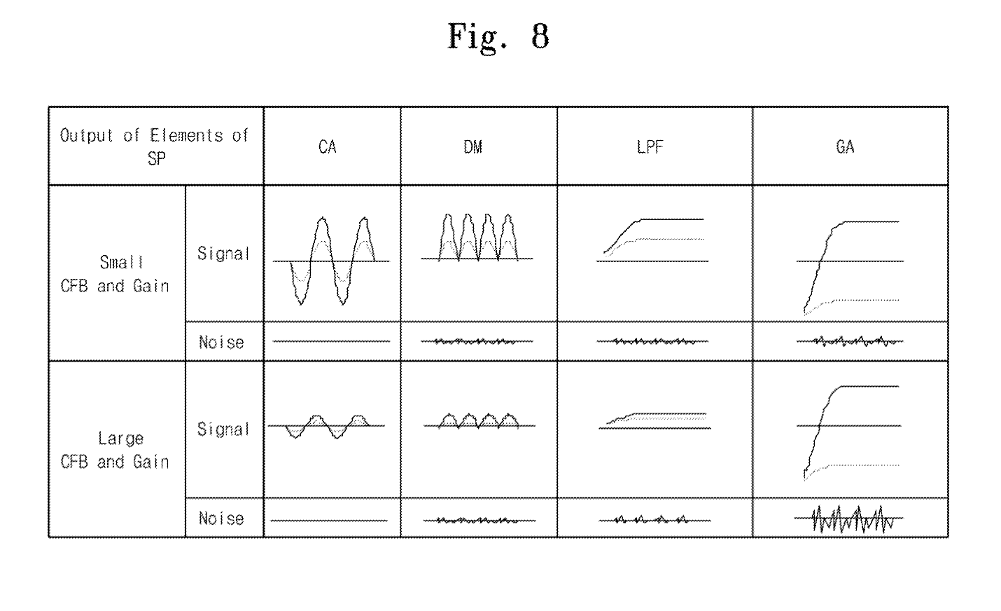

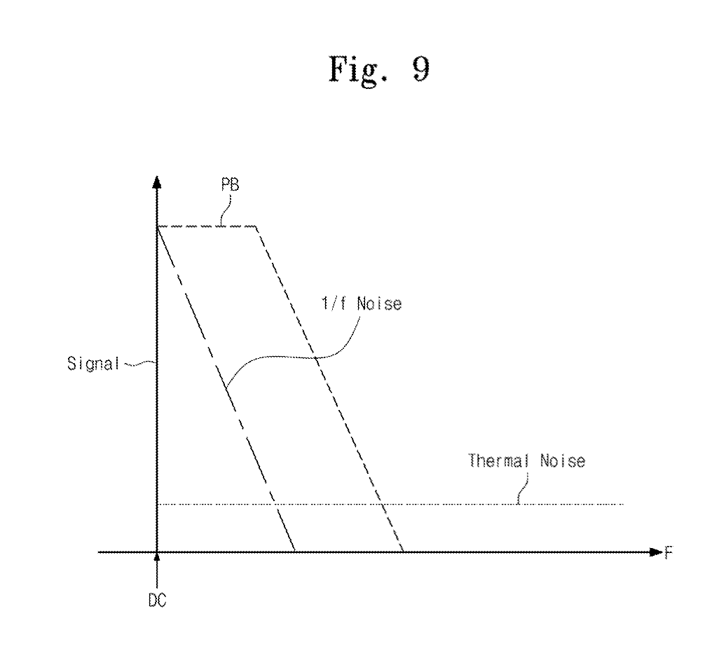

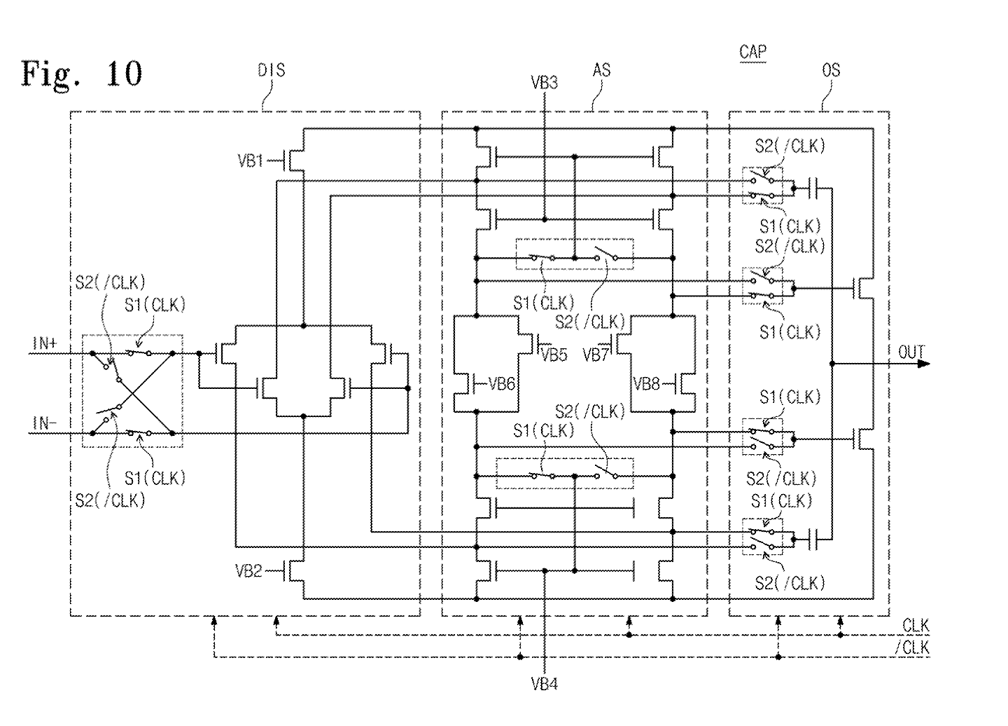

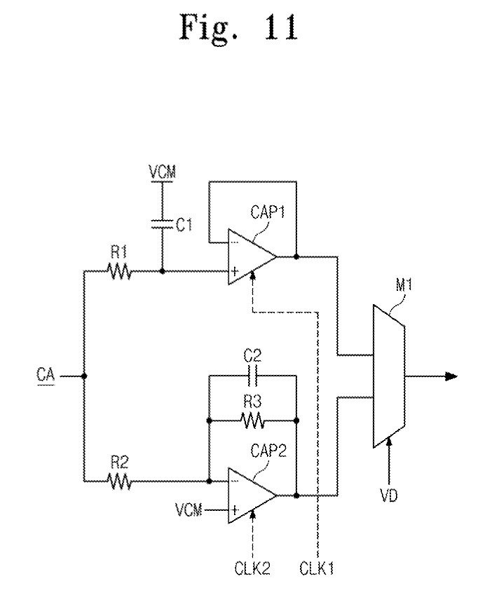

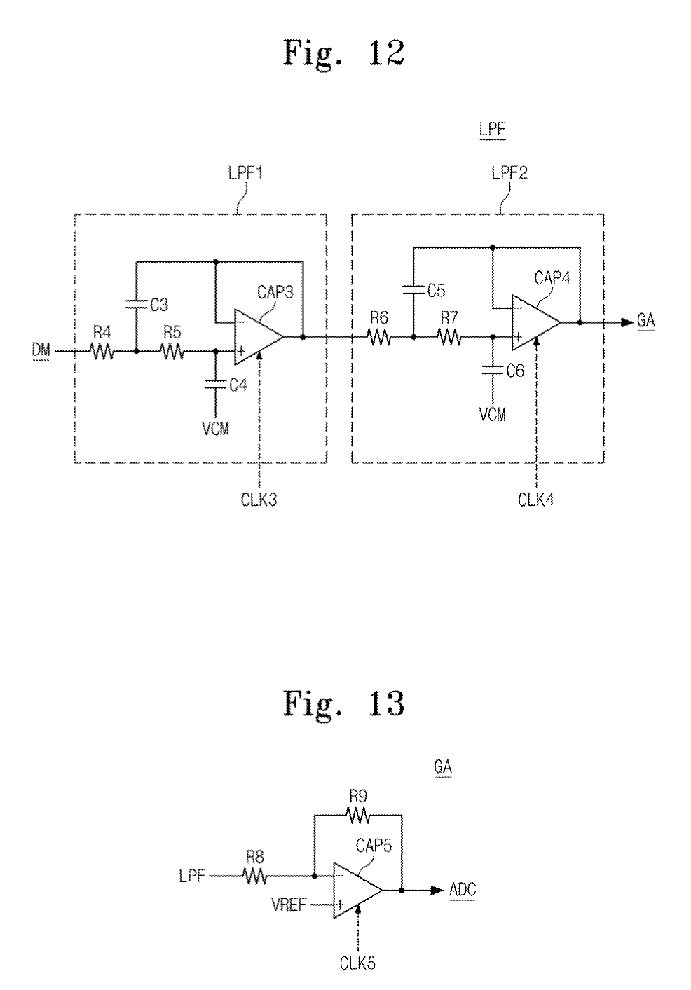

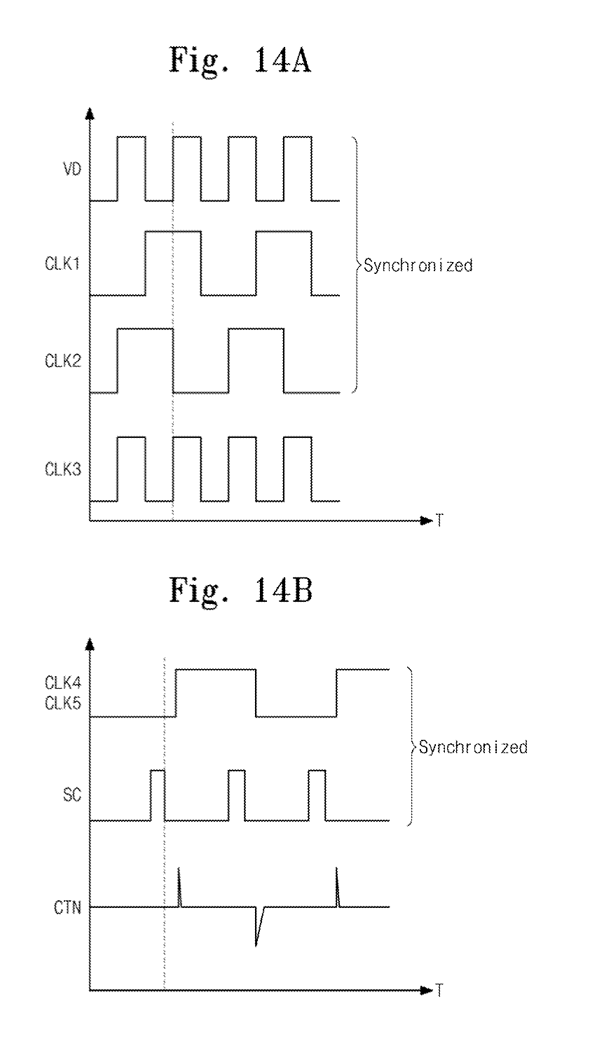

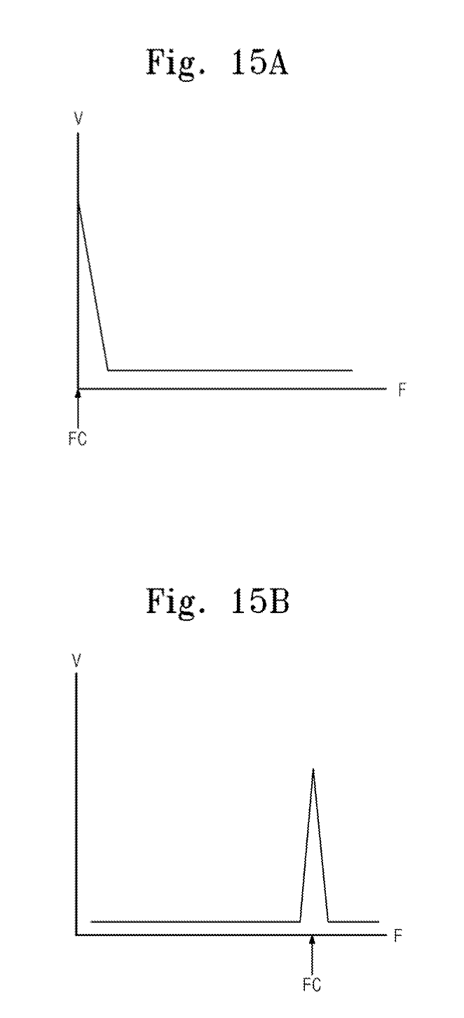

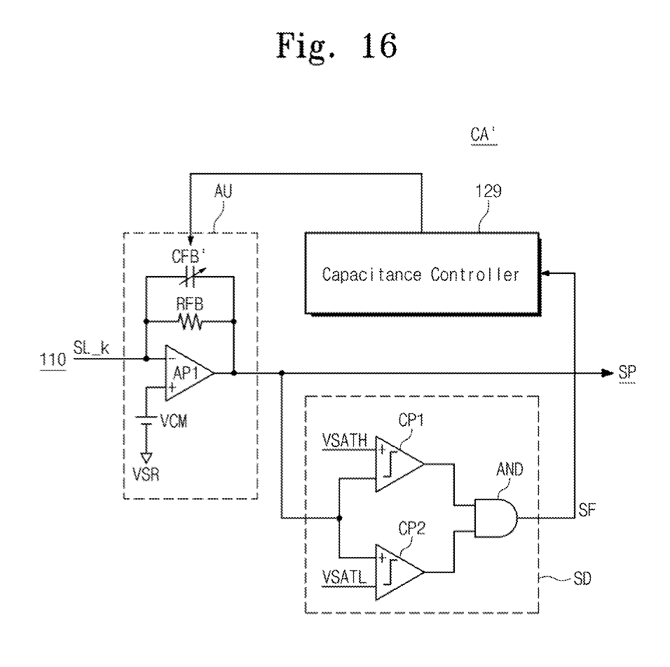

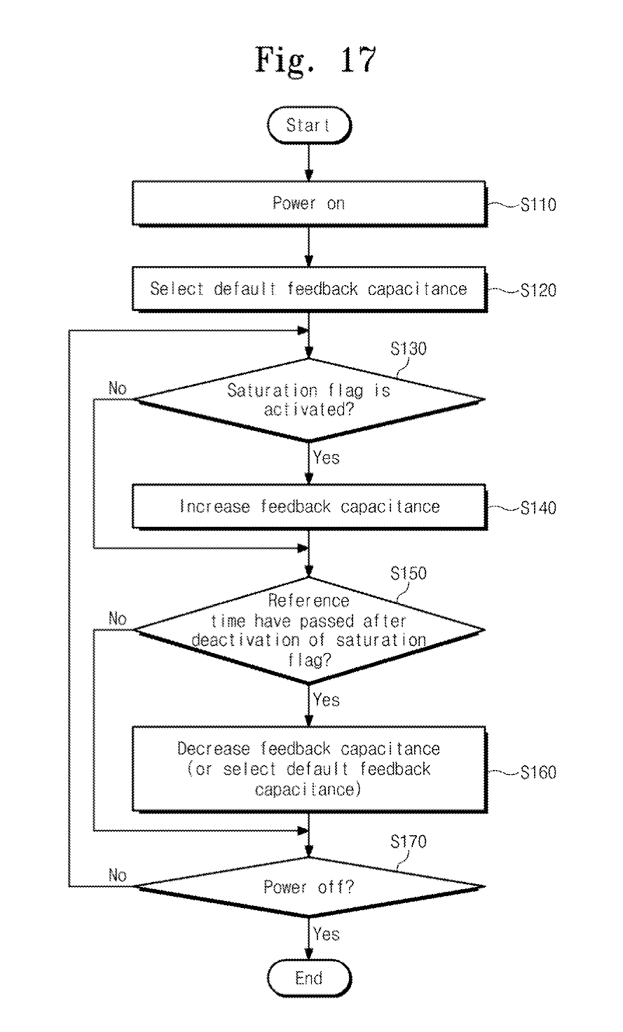

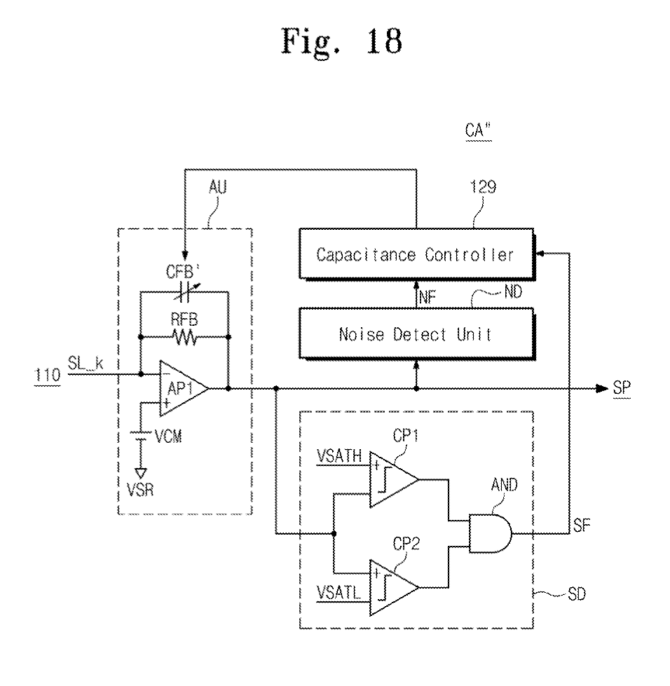

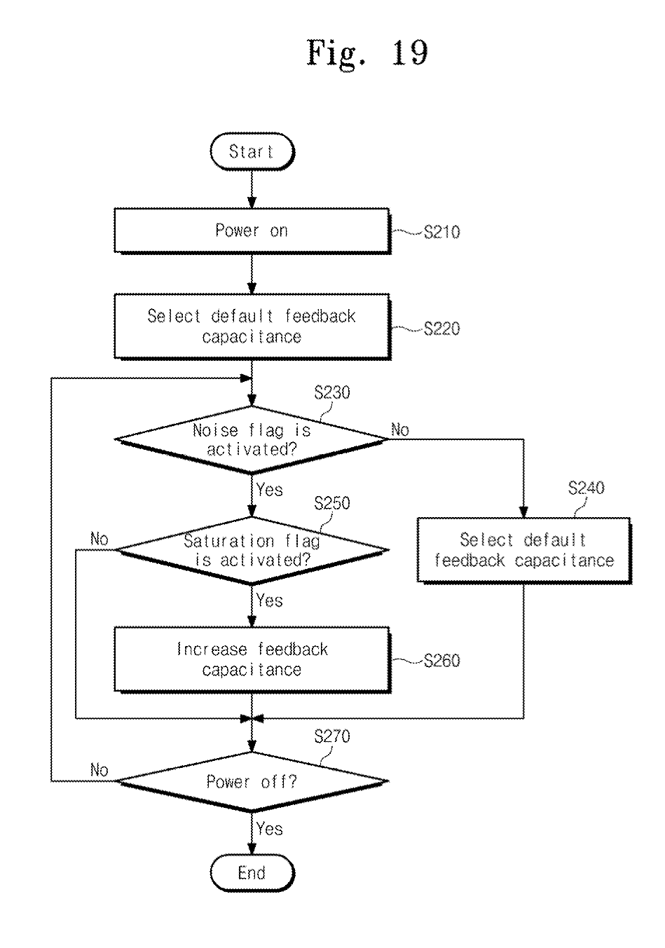

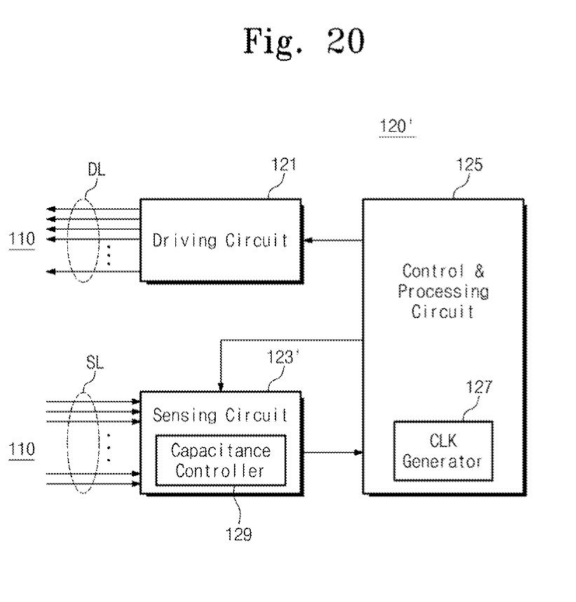

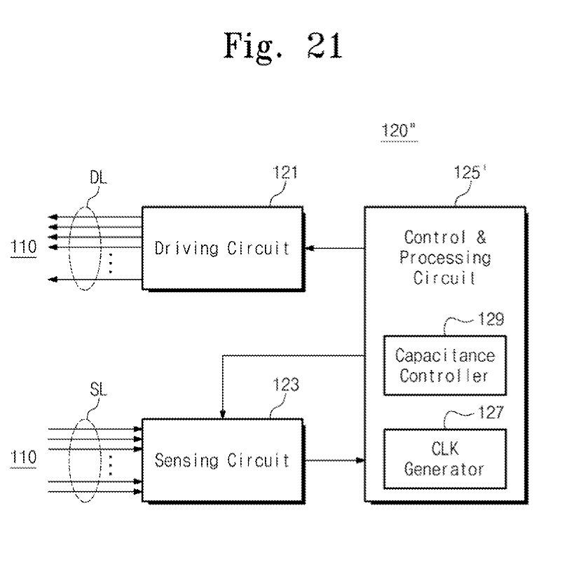

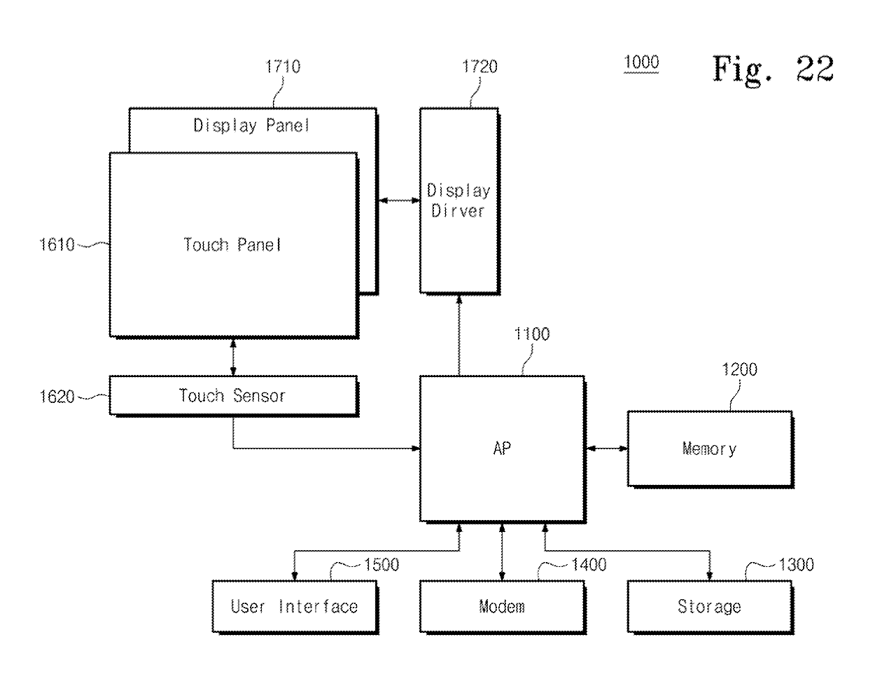

FIG. 5 is a detailed view illustrating one sensing unit S_k of the sensing units S_1 to S_m of FIG. 5. Referring to FIGS. 5 and 6, the charge amplifier CA may include an operational amplifier AP1, a feedback resistor RFB, and a feedback capacitor CFB.

A negative input node of the operational amplifier AP1 may be connected to the corresponding sensing line SL_k. A common voltage VCM may be supplied into a positive input node of the operational amplifier AP1. The feedback resistor RFB and the feedback capacitor CFB may be parallelly connected between the negative input node and an output node of the operational amplifier AP1.

The signal processor SP may include a demodulator DM, a low pass filter LPF, and a gain amplifier GA.

The demodulator DM is configured to perform an operation on the output signal of the charge amplifier CA and a demodulating signal VD to output the operated signal. For example, the output signal of the charge amplifier CA may have a negative polarity and a positive polarity. The demodulator DM may invert a signal having the negative polarity of the output signals of the charge amplifier CA. The demodulator DM may output a signal having the positive polarity.

The low pass filter LPF may filter the output signal of the demodulator DM.

The gain amplifier GA may amplify the output signal of the low pass filter LPF. The gain amplifier GA may amplify the output signal of the low pass filter LPF based on an offset voltage VOFF.

For example, the internal elements of the signal processor SP may interfere with various internal noises. The various internal noises may be a thermal noise, a 1/f noise, or the like. The noises are illustrated as noise model NM1 in the signal processor SP.

For example, since the internal noises are generated from the demodulator DM, the noise model NM1 may be provided between the demodulator DM and the low pass filter LPF. However, a position of the noise model NM1 is not limited to the above-described position.

FIG. 7 is an equivalent circuit diagram for explaining an operation of the touch panel 110 according to an embodiment of the inventive concept. One driving line DL_{—}i and one sensing line SL_{—}j are illustrated in FIG. 7. The driving line DL_{—}i and the sensing line SL_{—}j may include internal resistors R_DL and R_SL, respectively.

As shown in FIG. 2, the driving lines DL may be connected to the first conductive lines 133, and the sensing lines SL may be connected to the second conductive lines 115. The first and second conductive lines 113 and 115 are spaced in a specific distance from each other. A capacitance may exist between the first conductive lines 113 and second conductive lines 115. In FIG. 7, the capacitance is illustrated as a capacitor CM between the first conductive lines 113 and second conductive lines 115.

The pulse signal transmitted into the driving line DL_{—}i may be transmitted into the sensing line SL_{—}j through the capacitor CM.

When an external conductor contacts the touch area 111, a capacitance may be generated between the second conductive lines 115 and the external conductor. The external conductor may be a user's finger, but the external conductor is not limited thereto. The capacitance is illustrated as a capacitor CF in FIG. 7. When the capacitance of the capacitor CF is generated, current flowing from the driving line DL_{—}i toward the sensing line SL_{—}j may be changed in flow direction. The plurality of sensing units S_1 to S_m may sense variations of current received from the corresponding sensing lines SL 1 to SL_m, respectively. The control and processing circuit 125 may determine a position touched on the touch area 111 based on the sensed results.

When the external conductor contacts the touch area 111, various environment noises may be transferred through the capacitor CF generated by the external conductor. The environment noises transferred through the capacitor CF are illustrated as a voltage source VNF, as illustrated in FIG. 7. The voltage source VNF and the capacitor CF may form a noise model NM2.

Various electronic components SB may be provided under the touch panel 110. For example, electronic components may be provided under the touch panel 110. The electronic components may be a display panel or a board, but the electronic components are not limited thereto. A capacitance may be generated between the touch panel 110 and the electronic components SB provided under the touch panel 110. The capacitance is illustrated as capacitors CS1 and CS2 in FIG. 7. The capacitor CS1 may represent the capacitance generated between the first conductive lines 113 and the electronic components SB, and the capacitor CS2 may represent the capacitance generated between the second conductive lines 115 and the electronic components SB.

The various environment noises may be transferred through the capacitors CS1 and CS2 generated between the touch panel 110 and the electronic components SB. The environment noises transferred through the capacitors CS1 and CS2 are illustrated as a voltage source VND in FIG. 7. The voltage source VND, the capacitors CS1 and CS2 may form a noise model NM3.

Referring to FIG. 6, the charge amplifier CA may include the operational amplifier AP1. If an input voltage gets out of an operating range of the charge amplifier CA, the operational amplifier AP1 may be saturated to operate abnormally. If environment noises introduced from the outside are strong, the operational amplifier AP1 may be saturated, and thus abnormal sensing may be performed.

Thus, the capacitance of the feedback capacitor CFB of the operational amplifier AP1 may be set in consideration of the environment noises.

Referring to FIGS. 6 and 7, the charge amplifier CA is configured to perform an amplification operation thereof according to rates of the capacitors CM, CS1, CS2, and CF to the capacitance of the feedback capacitor CFB. When the capacitance of the feedback capacitor CFB decreases, the amplification factor of the charge amplifier CA may increase. When the capacitance of the feedback capacitor CFB decreases, the amplification factor of the charge amplifier CA may decrease. When the capacitance of the feedback capacitor CFB is set to a low value enough to endure the environment noises, the charge amplifier CA may not be saturated by the environment noises so as to operate normally.

When the amplification factor of the charge amplifier CA decreases, the amplification factor of the gain amplifier GA should relatively increase. When amplification factor of the gain amplifier GA increases, the internal noises illustrated as the noise model NM1 may be amplified together, as illustrated in FIG. 8.

The output signals and noises of each of the elements in the signal processor SP are illustrated in FIG. 8. The output signals might not include noises.

The output signals when the user's touch does not occur is illustrated as solid lines in FIG. 8. The output signals when the user's touch occurs is illustrated as dotted lines in FIG. 8.

Referring to FIGS. 6 to 8, the charge amplifier CA may output a signal similar to a sinusoidal signal. The output signal of the charge amplifier CA may be a signal in which the environment noises are added to the pulse signal outputted from the driving circuit 110. The output signal of the charge amplifier CA may vibrate around the common voltage VCM.

The demodulator DM may invert a negative polarity of the output signals of the charge amplifier CA into a positive polarity to output the inverted signal. Internal noises may be generated in the demodulator DM.

The low pass filter LPF may filter the output signal of the demodulator DM to convert the filtered signal into direct current (DC). Internal noises generated in the low pass filter LPF may be added to the internal noises generated in the demodulator DM.

The gain amplifier GA may amplify the output signal of the low pass filter LPF. The internal noises inputted into the gain amplifier GA may also be amplified.

When the feedback capacitance CFB is set to a low value to prevent the charge amplifier CA from being saturated by the noises, the amplification factor of the gain amplifier GA may be set to a high value. The amplification of the internal noises may cause a malfunction.

FIG. 9 is a graph illustrating the internal noises. Referring to FIG. 9, the internal noises may include a thermal noise and a 1/f noise.

The thermal noise may be uniformly distributed over the entire frequency band. Most of the thermal noise may be removed by the low pass filter LPF.

The 1/f noise may be distributed inversely proportional to frequency domain. Also, the 1/f noise may be widely distributed around the DC. The 1/f noise may not be removed by the low pass filter LPF.

The touch sensing apparatus according to an embodiment of the inventive concept may include the operational amplifier whose polarity is converted in response to a clock signal. When the operational amplifier performs a normal operation, the 1/f noise may have a normal phase. When polarity of the operational amplifier is inverted to perform an inversion operation, the 1/f noise may have an inverted phase. When the operational amplifier performs the normal operation and the inversion operation, the 1/f noise may be demodulated by the clock signal to move to a high-frequency band. The 1/f noise moving to the high-frequency band may be removed by the low pass filter LPF.

FIG. 10 is a circuit diagram of an operational amplifier CAP according to an embodiment of the inventive concept. Referring to FIG. 10, the operational amplifier CAP may include a differential input unit DIS, an amplification unit AS, and an output unit OS.

The operational amplifier CAP may operate in response to a clock signal CLK. For example, the operational amplifier CAP may operate in response to the clock signal CLK or an inverted clock signal /CLK. The operational amplifier CAP may amplify a difference between two input signals in a forward direction (a positive direction) in response to the clock signal. The operational amplifier CAP may amplify a difference between two input signals in a backward direction (a negative direction) in response to the inverted clock signal /CLK.

For example, the operational amplifier CAP may amplify a value of a voltage level at a positive node IN+ minus a voltage level at a negative node IN− in response to the clock signal CLK. The above-described operation may be an amplification operation (or the normal operation) in the forward direction. The operational amplifier CAP may amplify a value of the voltage level at the negative node IN₋ minus the voltage level at the positive node IN+ in response to the inverted clock signal /CLK. The above-described operation may be an amplification operation (or the inversion operation) in the backward direction. The operational amplifier CAP may perform the normal operation when the clock signal CLK is at a high level. The operational amplifier CAP may perform the inversion operation when the inverted clock signal /CLK is at a high level.

The differential input unit DIS may include a plurality of transistors and a plurality of switches S1s and S2s. The differential input unit DIS may be configured to receive the clock signal CLK, the inverted clock signal /CLK, and bias voltages VB1 and VB2. The plurality of switches S1s and S2s may convert polarity of the signals received through the input nodes IN+ and IN− in response to the clock signal CLK or the inverted clock signal /CLK.

The first switches S1s are synchronized with the clock signal CLK, and the second switches S2s may be synchronized with the inverted clock signal /CLK. The first switches S1s may be switched on when the clock signal CLK is at the high level and be switched off when the clock signal CLK is at the low level. Also, the second switches S2s may be switched on when the inverted clock signal /CLK is at the high level and be switched off when the inverted clock signal /CLK is at the low level. The first switches S1s may be on when the clock signal CLK is at the high level, and the second switches S2s may be switched on when the clock signal CLK is at the low level. The bias voltages VB1 and VB2 may be provided to transistors to control the transistors. The transistors may operate as current sources, respectively.

The differential input unit DIS may detect a difference between the input signals received through the input nodes IN+ and IN− in response to the clock signal CLK or the inverted clock signal /CLK. The differential input unit DIS may be synchronized with the clock signal CLK to detect a value of a voltage level of the positive input node IN+ minus a voltage level of the negative input node IN−. The detected value may be a first detection signal.

The differential input unit DIS may be synchronized with the inverted clock signal /CLK to detect a value of a voltage level at the negative input node IN− minus a voltage level at the positive input node IN+. The differential input unit DIS may detect a value of a voltage level at the positive input node IN+ minus a voltage level at the negative input node IN− in response to a first edge (a rising edge) of the clock signal CLK. The differentia input unit DIS may detect a value of the voltage level at the negative input node IN− minus the voltage level at the positive input node IN+ in response to a second edge (a falling edge) of the clock signal CLK. The detected value may be a second detection signal.

For example, it may be understood that the switches S1s and S2s perform a chopping operation. The operational amplifier CAP may be a chopping operational amplifier.

Since the switches S1s synchronized with the clock signal CLK and the switches S2s synchronized with the inverted clock signal /CLK are provided in the differential input unit DIS, polarity of the differential input unit DIS may vary in response to the clock signal CLK or the inverted clock signal /CLK. However, a structure of the differential input unit DIS is not limited thereto. For example, the differential input unit DIS may be realized by adding the switches S1s and S2s to various locations in the operational amplifier CAP.

The amplification unit AS may amplify the signal transmitted from the differential input unit DIS in response to the clock signal CLK or the inverted clock signal /CLK. The amplification unit AS may be synchronized with the clock signal CLK to amplify the first detection signal (e.g., a value of the signal level received through the positive input node IN+ minus the signal level received through the negative input node IN−) transmitted from the differential input unit DIS in the forward direction mode. The amplification unit AS may output an amplified first detection signal in the forward direction mode. The amplification unit AS may be synchronized with the inverted clock signal /CLK to amplify the second detection signal (e.g., a value of the signal level received through the negative input node IN− minus the signal level received through the positive input node IN+) transmitted from the differential input unit DIS in the reverse direction mode. The amplification unit AS may output an amplified second detection signal in the reverse direction mode.

The amplification unit AS may include a plurality of transistors and a plurality of switches S1s and S2s. The amplification unit AS may be configured to receive the clock signal CLK, the inverted clock signal /CLK, and bias voltages VB4 to VB8. The first switches S1s are synchronized with the clock signal CLK, and the second switches S2s may be synchronized with the inverted clock signal /CLK. The first switches S1s may be switched on when the clock signal CLK is at a high level and be switched off when the clock signal CLK is at a low level. Also, the second switches S2s may be switched on when the inverted clock signal /CLK is at a high level and be switched off when the inverted clock signal /CLK is at a low level. The first switches S1s may be switched on when the clock signal CLK is at the high level, and the second switches S2s may be switched on when the clock signal CLK is at the low level.

The bias voltages VB3 and VB4 may be provided to transistors to control the transistors. The transistors may operate as cascodes, respectively. The transistors operating as the cascodes may increase output resistance of the current sources. The bias voltages VB5 to VB8 may be basic bias voltages provided into the operational amplifier CAP.

Since the switches S1s synchronized with the clock signal CLK to operate and the switches S2s synchronized with the inverted clock signal /CLK to operate are provided in the amplification unit AS, polarity of the amplification unit AS may vary in response to the clock signal CLK or the inverted clock signal /CLK. A structure of the amplification unit AS is not limited thereto. For example, the amplification unit AS may be realized by adding the switches S1s and S2s to various locations in the amplification units of the operational amplifier CAP.

The output unit OS may include a plurality of transistors and a plurality of switches S1s and S2s. The output unit OS may be configured to receive the clock signal CLK and the inverted clock signal /CLK. The first switches S1s may be synchronized with the clock signal CLK, and the second switches S2s may be synchronized with the inverted clock signal /CLK. The first switches S1s may be switched on when the clock signal CLK is at a high level and be switched off when the clock signal CLK is at a low level. Also, the second switches S2s may be switched on when the inverted clock signal /CLK is at a high level and be switched off when the inverted clock signal /CLK is at a low level. The first switches S1s may be switched on when the clock signal CLK is at the high level, and the second switches S2s may be switched on when the clock signal CLK is at the low level.

The output unit OS may amplify the signal transmitted from the amplification unit AS in response to the clock signal CLK and the inverted clock signal /CLK. The output unit OS may be synchronized with the clock signal CLK to output the first amplification signal transmitted from the amplification unit AS.

The output unit OS may be synchronized with the inverted clock signal /CLK to output the first amplification signal transmitted from the amplification unit AS.

Since the switches S1s synchronized with the clock signal CLK to operate and the switches S2s synchronized with the inverted clock signal /CLK to operate are provided in the output unit OS, polarity of the output unit OS may vary in response to the clock signal CLK or the inverted clock signal /CLK. A structure of the output unit OS is not limited thereto. For example, the output unit OS may be realized by adding the switches S1s and S2s to various locations in the operational amplifier CAP.

The differential input unit DIS, the amplification unit AS, and the output unit OS may operate in response to the clock signal CLK and the inverted clock signal /CLK. For example, the operational amplifier CAP may receive the clock signal CLK and the inverted clock signal /CLK from the outside. For another example, the operational amplifier CAP may receive the clock signal CLK from the outside. The operational amplifier CAP may further include a unit (e.g., an inverter) for inverting the clock signal CLK received from the outside to generate the inverted clock signal /CLK. However, a structure or method to generate the clock signals is not limited thereto.

FIG. 11 is a circuit diagram of the demodulator DM according to an embodiment of the inventive concept. Referring to FIG. 11, the demodulator DM may include first and second operational amplifiers CAP1 and CAP2, a multiplexer M1, capacitors C1 and C2, and resistors R1, R2, and R3.

The first operational amplifier CAP1 may operate in response to a first clock signal CLK1. Polarity of the first operational amplifier CAP1 may vary in response to the first clock signal CLK1. The first operational amplifier CAP1 may include the operational amplifier CAP described with reference to FIG. 10.

A positive input node of the first operational amplifier CAP1 may be connected to an output node of the charge amplifier CA through the first resistor R1 to receive the common voltage VCM through the first capacitor C1. A negative input node of the first operational amplifier CAP1 may be connected to an output node of the first operational amplifier CAP1. The output node of the first operational amplifier CAP1 may be connected to the multiplexer M1.

The first operational amplifier CAP1 may include a voltage follower for transmitting a voltage of the output node of the charge amplifier CA. For example, the first operational amplifier CAP1 may be a voltage follower having an offset common voltage VCM.

The second operational amplifier CAP2 may operate in response to a second clock signal CLK2. The second operational amplifier CAP2 may have a polarity varying in response to the second clock signal CLK2. The second operational amplifier CAP2 may include the operational amplifier CAP described with reference to FIG. 10.

The common voltage VCM may be supplied into a positive input node of the second operational amplifier CAP2. A negative input node of the second operational amplifier CAP2 may be connected to the output node of the charge amplifier CA through the second resistor R2 and may be connected to an output node of the second operational amplifier CAP2 through the third resistor R3 and the second capacitor C2. The output node of the second operational amplifier CAP2 may be connected to the multiplexer M1.

The second operational amplifier CAP2 may serve as an amplifier for amplifying the voltage of the output node of the charge amplifier CA, and may output the amplified voltage according to a resistance ratio of the second resistor R2 to the third resistor R3. The second operational amplifier CAP2 may amplify a value of the common voltage level VCM minus the voltage level of the output node of the charge amplifier CA. For example, the resistance ratio of the second resistor R2 to the third resistor R3 may be set such that the output voltage level of the second operational amplifier CAP2 is equal or similar to that of the output voltage level of the first operational amplifier CAP1. For example, the resistance ratio of the second resistor R2 to the third resistor R3 may be substantially 1:1.

When the charge amplifier CA has an output voltage greater than the common voltage VCM, and the second operational amplifier CAP2 has a output voltage level less than that of the common voltage VCM, the second operational amplifier CAP2 may output a voltage less than the common voltage VCM. When the charge amplifier CA has an output voltage level less than the common voltage VCM, the second operational amplifier CAP2 may have a output voltage level less than that of the common voltage VCM. The second operational amplifier CAP2 may have an offset common voltage VCM and invert the output voltage of the charge amplifier CA. The second operational amplifier CAP2 may serve as an inverter (e.g., an inversion amplifier).

The multiplexer M1 may select one of the output of the first operational amplifier CAP1 and the output of the second operational amplifier CAP2 in response to a demodulating signal VD. For example, the demodulating signal VD may be a pulse signal (e.g., a clock signal) synchronized with the pulse signal outputted from the driving circuit 121. The demodulating signal VD may have the same period and duty ratio as those of the pulse signal.

When the pulse signal outputted from the driving circuit 121 is at a high level, the output signal of the charge amplifier CA may be at a high level (or a low level). The multiplexer M1 may be synchronized with the demodulating signal VD to select one (e.g., the output of the CAP1) of the outputs of the first and second operational amplifiers CAP1 and CAP2. When the pulse signal is at a low level, the output signal of the charge amplifier CA may be at a low level (or a high level). The multiplexer M1 may be synchronized with the demodulating signal VD to select the other one (e.g., the output of the CAP2) of the outputs of the first and second operational amplifiers CAP1 and CAP2.

The multiplexer M1 may receive a signal swing in positive and negative directions with respect to the common voltage VCM from the charge amplifier CA. The multiplexer M1 may be synchronized with the demodulating signal VD to output a signal having one polarity (e.g., a positive or negative polarity).

For example, the first and second clock signals CLK1 and CLK2 may be transmitted from the clock generator 127 of the control and processing circuit (see reference numeral 125 of FIG. 3). The demodulator DM may further receive inverted signals of the first and second clock signals in addition to the first and second clock signals CLK1 and CLK2. However, the demodulator DM is not limited thereto. The inventive concept may be applied to various decoders using the operational amplifier CAP having the polarity varying in response to the clock signal CLK.

FIG. 12 is a circuit diagram of the low pass filter LPF according to an embodiment of the inventive concept. Referring to FIG. 12, the low pass filter LPF may include a first low pass filter LPF1 and a second low pass filter LPF2.

The first low pass filter LPF1 may include a third operational amplifier CAP3, fourth and fifth resistors R4 and R5, and third and fourth capacitors C3 and C4.

The third operational amplifier CAP3 may operate in response to the third clock signal CLK3. Polarity of the third operational amplifier CAP3 may vary in response to the third clock signal CLK3. The third operational amplifier CAP3 may include the operational amplifier CAP described with reference to FIG. 10.

A positive input node of the third operational amplifier CAP3 may be connected to the fifth resistor R5 to receive the common voltage VCM through the fourth capacitor C4. A negative input node of the third operational amplifier CAP3 is connected to the third capacitor C3 and an output node of the third operational amplifier CAP3. The fifth resistor R5 may be connected to the fourth resistor R4 and the third capacitor C3. The fourth resistor R4 may be connected to an output node of the demodulator DM.

The second filter LPF2 may include a fourth operational amplifier CAP4, sixth and seventh resistors R6 and R7, and fifth and sixth capacitors C5 and C6.

The fourth operational amplifier CAP4 may operate in response to a fourth clock signal CLK4. Polarity of the fourth operational amplifier CAP4 may vary in response to the fourth clock signal CLK4. The fourth operational amplifier CAP4 may include the operational amplifier CAP described with reference to FIG. 10.

A positive input node of the fourth operational amplifier CAP4 may be connected to the seventh resistor R7 to receive the common voltage VCM through the sixth capacitor C6. A negative input node of the fourth operational amplifier CAP4 may be connected to the fifth capacitor C5 and an output node of the fourth operational amplifier CAP4. The seventh resistor R7 is connected to the sixth resistor R6 and the fifth capacitor C5. The sixth resistor R6 is connected to an output node of the first filter LPF1.

Each of the first low pass filter LPF1 and the second low pass filter LPF2 may perform a low pass filtering function. The first and second filters LPF1 and LPF2 may have the same structure.

For example, the third and fourth clock signals CLK3 and CLK4 may be transmitted from the clock generator 127 of the control and processing circuit (see reference numeral 125 of FIG. 3). The demodulator DM may further receive inverted signals of the third and fourth clock signals in addition to the third and fourth clock signals CLK3 and CLK4.

For example, a specific structure of the low pass filter LPF is illustrated in FIG. 12. However, the low pass filter LPF is not limited thereto. The inventive concept may be applied to various low pass filters using the operational amplifier CAP whose polarity varies in response to the clock signal CLK.

FIG. 13 is a circuit diagram of the gain amplifier GA according to an embodiment of the inventive concept.

Referring to FIG. 13, the gain amplifier GA may include a fifth operational amplifier CAP5 and eighth and ninth resistors R8 and R9.

The fifth operational amplifier CAP5 operates in response to a fifth clock signal CLK5. Polarity of the fifth operational amplifier CAP5 may vary in response to the fifth clock signal CLK5. The fifth operational amplifier CAP5 may include the operational amplifier CAP described with reference to FIG. 10.

A reference voltage VREF may be supplied into a positive input node of the fifth operational amplifier CAP5.

A negative input node of the fifth operational amplifier CAP5 is connected to the output node of the low pass filter LPF through the eighth resistor R8 and an output node of the fifth operational amplifier CAP5 through the ninth resistor R9. The output node of the fifth operational amplifier CAP5 may be connected to the analog-to-digital converter ADC.

The gain amplifier GA may amplify the output signal of the low pass filter LPF according to a resistance ratio of the eighth resistor R8 to the ninth resistor R9. The gain amplifier GA may have an offset reference voltage VREF.

For example, the fifth clock signal CLK5 may be transmitted from the clock generator 127 of the control and processing circuit (see reference numeral 125 of FIG. 3). The gain amplifier GA may further receive an inverted signal of the fifth clock signal in addition to the fifth clock signal CLK5. However, the gain amplifier is not limited thereto. The inventive concept may be applied to various gain amplifiers using the operational amplifier CAP whose polarity varies in response to the clock signal CLK.

FIG. 14A is a timing diagram illustrating an example of the clock signals supplied into the demodulator DM and the low pass filter LPF. Referring to FIGS. 6, 11 to 13, and 14A, the multiplexer M1 of the demodulator DM may select an output signal in response to the demodulating signal VD. The demodulating signal VD may be a signal (e.g., a clock signal) equal to the pulse signal outputted from the driving circuit 121.

The first and second clock signals CLK1 and CLK2 respectively supplied into the first and second operational amplifiers CAP1 and CAP2 may be synchronized with the demodulating signal VD. The duty ratios of the first clock signal CLK1 and the second clock signal CLK2 may be substantially same as the duty ratio of the demodulating signal VD. The periods and pulse widths of the first clock signal CLK1 and the second clock signal CLK2 may be substantially twice as great as the demodulating signal VD. A phase of the first clock signal CLK1 may be different from a phase of the second clock signal CLK2. The first clock signal CLK1 may be synchronized with a falling edge of the demodulating signal VD, and the second clock signal CLK2 may be synchronized with a rising edge of the demodulating signal VD.

When the demodulating signal VD is transited from a high level to a low level, the multiplexer M1 may select an output signal of the second operational amplifier CAP2 in which the second clock signal CLK2 is supplied. The second clock signal CLK2 may be at a high level or at a low level in a state in which a predetermined time elapses after the second clock signal CLK2 is transited into the high level (or the low level). The predetermined time may be a quarter period of the demodulating clock signal. When the chopping operation for changing the polarity is performed by the second operational amplifier CAP2, transient response may occur in the second operational amplifier CAP2. The transient response may be dissipated after a predetermined time elapses after the second clock signal CLK2 is transited into the high level (or the low level). When the chopping operation for changing the polarity is performed by the second operational amplifier CAP2, the output signal of the second operational amplifier CAP2 may be selected after the predetermined time elapses and the transient response may not exist within the selected output signal.

Similarly, when the demodulating signal VD is transited from a low level to a high level, the multiplexer M1 may select an output signal of the first operation amplifier CAP1 in which the first clock signal CLK1 is supplied. The first clock signal CLK1 may be at a high level or a low level in which a predetermined time elapses after the first clock signal CLK1 is transited into the high level (or the low level). The predetermined time may be a quarter period of the demodulating clock signal. When the chopping operation for changing the polarity is performed by the first operational amplifier CAP1, the output signal of the first operational amplifier CAP1 may be selected after the predetermined time elapses and the transient response may not exist within the selected output signal.

For example, each of the first clock signal CLK1 and the second clock signal CLK2 may be applied with various periods and duty ratios to avoid the transient response due to the chopping operation.

For example, each of the first clock signal CLK1 and the second clock signal CLK2 may have a frequency greater than the pass band of the low pass filter LPF.

The third clock signal CLK3 supplied into the operational amplifier CAP3 of the first low pass filter LPF1 of the low pass filter LPF may be the same as the demodulating signal VD. However, the third clock signal CLK3 may not be the same signal as the demodulating signal VD. For example, the third clock signal CLK3 may be a clock signal having a predetermined period and duty ratio.

FIG. 14B is a timing diagram illustrating the clock signals supplied into the low pass filter LPF, the gain amplifier GA, and the analog-to-digital converter ADC. Referring to FIGS. 6, 11 to 13, and 14B, the fourth clock signal CLK4 supplied into the second filter LPF2 of the low pass filter LPF and the fifth clock signal CLK5 supplied into the gain amplifier GA may be the same. A sampling clock signal SC may be supplied into the analog-to-digital converter ADC. The analog-to-digital converter ADC may perform a sampling operation in response to the sampling clock signal SC.

The fourth and fifth clock signals CLK4 and CLK5 may be synchronized with the sampling clock signal SC. A rising edge of each of the fourth and fifth clock signals CLK4 and CLK5 may be delayed than a falling edge of the sampling clock signal SC. The rising edges of the fourth and fifth clock signals CLK4 and CLK5 may exist within a low level period of the sampling clock signal SC.

For example, the fourth and fifth operation amplifiers CAP4 and CAP5 may be synchronized, respectively with the rising and falling edges of the fourth and fifth clock signals CLK4 and CLK5 to perform the chopping operation for changing the polarity. When the chopping operation is performed, the transient response may occur. For example, the transient response due to the chopping operation is illustrated as a signal CTN in FIG. 14B.

Referring to the timing chart of FIG. 14B, the chopping operation may be performed by the fourth and fifth operational amplifiers CAP4 and CAP5, and then the sampling operation may be performed in response to the sampling clock signal SC after a predetermined time elapses. When the analog-to-digital converter ADC performs the sampling operation, the transient response due to the chopping operation may not be sampled.

FIG. 15A is an exemplary graph illustrating a frequency response of a 1/f noise generated in each of elements of a signal processor SP. FIG. 15B is a graph illustrating a frequency response of a 1/f noise varying by the chopping operation for changing a polarity in the operational amplifiers CAP1 to CAP5 of the signal processor SP. Referring to FIGS. 15A and 15B, a center frequency FC of a 1/f noise may move to a high-frequency band by the chopping operation. For example, the center frequency FC may move to frequencies of the clock signals CLK1 to CLK5 supplied into the operational amplifiers CAP1 to CAP5 or harmonic frequencies of the frequencies of the clock signals CLK1 to CLK5.

When the frequencies of the clock signals CLK1 to CLK5 supplied into the operational amplifiers CAP1 to CAP5 are set to be greater than that of the pass band of the low pass filter LPF, the 1/f noise may be removed by the low pass filter and. Interference with the 1/f noise may not occur and gain of the gain amplifier GA may increase.

FIG. 16 is a view of a charge amplifier CA′ according to an embodiment of the inventive concept. Referring to FIG. 16, the charge amplifier CA′ may include an amplification unit AU, a saturation detector SD, and a capacitance controller CC.

The amplification unit AU may have the same structure as the charge amplifier CA described with reference to FIG. 6 except that a feedback capacitor CFB′ is provided as a variable capacitor.

The saturation detector SD may receive an output signal of the amplification unit AU to detect whether an operational amplifier AP1 of the amplification unit AU is saturated. The amplification unit AU may include a logic AND gate AND, a first comparator CP1, and a second comparator CP2.

The first comparator CP1 may compare the output signal of the amplification unit AU with a high level saturation voltage VSATH. The high level saturation voltage VSATH may be outputted when the operational amplifier AP1 is saturated to a high level. When the output voltage of the amplification unit AU is less than the high level saturation voltage VSATH, the first comparator CP1 may output a logic low signal. When the output voltage of the amplification unit AU reaches the high level saturation voltage VSATH, the first comparator CP1 may output a logic high signal.

The second comparator CP2 may compare the output signal of the amplification unit AU with a low level saturation voltage VSATL. The low level saturation voltage VSATL may be outputted when the operational amplifier AP1 is saturated to a low level. When the output voltage of the amplification unit AU is less than the low level saturation voltage VSATL, the second comparator CP2 may output a logic low signal. When the output voltage of the amplification unit AU reaches the low level saturation voltage VSATL, the second comparator CP2 may output a logic high signal.

The logic AND gate AND may perform a logic AND operation to the output signals of the first comparator CP1 and the second comparator CP2, and the logic AND gate may output the resultant signal.

If the operational amplifier AP1 is not saturated, the first comparator CP1 may output a logic low signal and the second comparator CP2 may output a logic high signal. The logic AND gate AND may output a logic low signal.

If the operational amplifier AP1 is saturated, the first comparator CP1 may output a logic high signal and the second comparator CP2 may output a logic high signal. The logic AND gate AND may output a logic high signal.

The saturation detector SD may output a flag signal SF indicating that the operational amplifier AP1 is saturated. The saturation detector SD may output a saturation flag signal SF having a logic high signal when the operational amplifier AP1 is saturated. The saturation detector SK may output a saturation flag signal SF having a logic low signal when the operational amplifier AP1 is not saturated.

The capacitance controller CC may receive the saturation flag signal SF from the saturation detector SD. The capacitance controller CC may control a capacitance of the feedback capacitor CFB′ of the amplification unit AU in response to the received saturation flag signal SF. For example, the capacitance controller CC may increase the capacitance of the feedback capacitor CFB′ in response to the saturation flag signal SF indicating that the operational amplifier AP1 is saturated. When the capacitance of the feedback capacitor CFB′ increases, the amplification factor of the amplification unit AU may decrease. The operational amplifier AP1 may be released from the saturated state.

FIG. 17 is a flowchart illustrating a process of operating the charge amplifier CA′ of FIG. 16. Referring to FIGS. 16 and 17, in an operation S110, a power may be applied to the charge amplifier CA′. The power may be applied to a touch sensing apparatus (see reference numeral 100 of FIG. 1).

In an operation S120, the capacitance controller CC may select the capacitance of the feedback capacitor CFB′ as a default value. The default value may be a preset value.

In an operation S130, the capacitance controller CC may determine whether the saturation flag signal SF is activated. If the saturation flag signal SF is activated, i.e., the operational amplifier AP1 is saturated, the capacitance controller CC may increase the capacitance of the feedback capacitor CFB′ in an operation S140. When the saturation flag signal SF is deactivated, the capacitance of the feedback capacitor CFB′ may not increase.

In an operation S150, it is determined whether a reference time elapses after the saturation flag signal SF is deactivated. If the reference time elapses after the saturation flag signal SF is deactivated, the feedback capacitance may decrease, or the default feedback capacitance may be selected in an operation S160. To check whether the reference time elapses, the capacitance controller CC may include a built-in timer or receive time information from the outside.

In an operation S170, when the power is turned off, the operation is ended. If the power is not turned off, the operation S130 may be performed again.

The capacitance controller CC may control the capacitance of the feedback capacitor CFB′ in response to the received saturation flag signal SF. For example, when the operational amplifier AP1 is saturated, the capacitance controller CC may repeatedly perform the operations S130 and S140 to gradationally increase the capacitance of the feedback capacitor CFB′ until the saturation of the operational amplifier AP1 is released from the saturated state. When the saturation of the operational amplifier AP1 is released, the saturation flag signal SF may be deactivated, and the capacitance of the feedback capacitor CFB′ may be maintained.

When the reference time increases after the saturation flag signal SF is deactivated, the capacitance controller CC may increase the capacitance of the feedback capacitor CFB′ or may select the default feedback capacitance.

When noises are introduced into the amplification unit AU to saturate the operation amplifier AP1, the capacitance of the feedback capacitor CFB′ may be adjusted to release the operational amplifier AP1 from the saturated state. When a predetermined time elapses after the saturation flag signal SF is deactivated, the capacitance of the feedback capacitor CFB′ may decrease, or the default feedback capacitance may be selected. When the noises are removed, the amplification factor of the amplification unit AU may be restored. The charge amplifier CA′ having strong resistance against the external noises may be provided.

FIG. 18 is a view of a charge amplifier CA″ according to another embodiment of the inventive concept. When compared to the charge amplifier CA′, the charge amplifier CA″ further may include a noise detector ND.

The noise detector ND may detect a noise from an output signal of an amplification unit AU. When the noise is detected from the output signal of the amplification unit AU, the noise detector ND may activate a noise flag signal NF. The noise flag signal NF is transmitted into a capacitance controller CC.

The capacitance controller CC may control a capacitance of a feedback capacitor CFB′ based on a saturation flag signal SF and the noise flag signal NF.

FIG. 19 is a flowchart illustrating a process of operating the charge amplifier CA″ of FIG. 18. Referring to FIGS. 18 and 19, in an operation S210, a power may be supplied.

In an operation S220, the capacitance of the feedback capacitor CFB′ may be selected as a default value.

In an operation S230, it may be determined whether the noise flag signal NF is activated. When the noise flag signal NF is deactivated, the capacitance of the feedback capacitor CFB′ may be selected as the default value in an operation S240. When the noise flag signal NF is activated, an operation S250 may be performed.

In the operation S250, it may be determined whether the saturation flag signal SF is activated. When the saturation flag signal SF is activated, the capacitance of the feedback capacitor CFB′ may increase in an operation S260.

In an operation S270, when the power is turned off, the operation may be ended. If the power is not turned off, the operation S230 may be performed again.

The charge amplifier CA″ may detect the noise by using the noise detector ND. When the noise is detected, and the operational amplifier AP1 is saturated, the capacitance of the feedback capacitor CFB′ may decreases to release the operational amplifier AP1 from the saturate state. When the noise is removed and the noise flag signal NF is deactivate, the capacitance of the feedback capacitor CFB′ may be selected as the default value. When the noise detector ND is adopted to reduce the noise, the amplification factor of the amplification unit AU may be restored to the default value.

FIG. 20 is a block diagram of a touch sensor 120′ according to an embodiment of the inventive concept. Referring to FIG. 20, the touch sensor 120′ may include a driving circuit 121, a sensing circuit 123′, and a control and processing circuit 125.

When compared to the touch sensor 120 described with reference to FIG. 3, the sensing circuit 123′ of the touch sensor 120′ may further include a capacitance controller 129.

As described with references to FIGS. 16 to 19, the capacitance controller 129 may be configured to control the capacitance of the feedback capacitor CFB′ of the charge amplifier CA′ or CA″. For example, the capacitance controller 129 may commonly control the capacitances of the feedback capacitors CFB′ of the charge amplifiers CA′ or CA″ in the plurality of sensing units S_1 to S_m of the sensing circuit 123′.

As described with references to FIGS. 16 to 19, the capacitances of the feedback capacitors CFB′ of the plurality of sensing units S_1 to S_m may be independently controlled. Alternatively, as shown in FIG. 20, the capacitances of the feedback capacitors CFB′ of the plurality of sensing units S_1 to S_m may be commonly controlled. However, a method or a structure for controlling the capacitances of the feedback capacitors CFB′ is not limited thereto.

FIG. 21 is a block diagram of a touch sensor 120″ according to an embodiment of the inventive concept. Referring to FIG. 21, the touch sensor 120″ may include a driving circuit 121, a sensing circuit 123, and a control and processing circuit 125′.

When compared to the touch sensor 120 described with reference to FIG. 3, the sensing circuit 125′ in the touch sensor 120″ further includes a capacitance controller 129.

The capacitance controller 129 may independently control the capacitances of the feedback capacitors CFB′ of the plurality of sensing units S_1 to S_m. Alternatively, the capacitance controller 129 may commonly control the capacitances of the feedback capacitors CFB′ of the plurality of sensing units S_1 to S_m. However, a method or a structure for controlling the capacitances of the feedback capacitors CFB′ is not limited thereto.

As described with reference to FIGS. 16 to 20, the capacitance controller 129 may be provided in the sensing circuit 123 or 123′. Also, as described with reference to FIG. 21, the capacitance controller 129 may be provided in the control and processing circuit 125′. position of the capacitance controller 129 is not limited thereto.

FIG. 22 is a block diagram of a mobile device 1000 according to an embodiment of the inventive concept. Referring to FIG. 22, the mobile device 1000 may include an application processor 1100, a memory 1200, a storage 1300, a modem 1400, an user interface 1500, a touch panel 1610, a touch sensor 1620, display panel 1710, and display driver 1720.

The application processor 1100 may control an overall operation of the mobile device 1000 to perform a logic AND.

The memory 1200 may be an operation memory of the application processor 1100. The memory 1200 may include a random access memory (RAM). The memory 1200 may include nonvolatile memories such as phase-change random-access memory (PRAM), magnetoresistive random-access memory (MRAM), resistive random-access memory (RRAM), ferroelectric random-access memory (FRAM), flash memories, or the like. The memory 1200 may include volatile memories such as dynamic random-access memory (DRAM), synchronous dynamic random-access memory (SDRAM), or the like. However, the memory 1200 is not limited thereto.

The storage 1300 may be an auxiliary storage of the mobile device 1000.

The storage 130 may include the nonvolatile memories. The storage 1300 may include the nonvolatile memories such as MRAM, PRAM, FRAM, RRAM, or the like. The storage 1300 may include a hard disk driver (HDD). However, the storage 1300 is not limited thereto.

When the memory 1200 and the storage 1300 include the same kind of nonvolatile memory, the memory 1200 and the storage 1300 may be integrated as one component.

The modem 1400 may wiredly or wirelessly communicate with an external device according to the control of the application processor 1100. The modem 1400 may perform communication with an external device according to wireless communication standards such as WiFi, long-term evolution (LTE), code-division-multiple-access (CDMA), global system for mobile communication (GSM), WiMAX, near-field communication (NFC), Bluetooth, or the like. The modem 1400 may perform communication with an external device according to wired communication standards such as USB, IEEE 1394 interface, PCI, serial advance technology attachment (SATA), Ethernet, or the like. However, the modem 1400 is not limited thereto.

The user interface 1500 may exchange a signal with a user according to the control of the application processor 1100. The user interface 1500 may include user input interfaces such as keyboards, buttons, microphones, cameras, or the like. The user interface 1500 may include user output interfaces such as speakers, motors, lamps, or the like. However, the user interface 1500 is not limited thereto.

The touch panel 1610 and the touch sensor 1620 may correspond to the touch panel 110 and the touch sensor 120 which are disposed with reference to FIGS. 1 to 20, respectively. The touch panel 1610 and the touch sensor 1620 may be included in the user interface 1500.

The display panel 1710 may include display panels such as LCDs, AMOLEDs, or the like. The display driver 1720 may include drivers for driving the display panels. The display panel 1710 and the display driver 1720 may be included in the user interface 1500. However, the display panel 1710 is not limited thereto.

The touch panel 1610 and the display panel 1710 may have a multilayer structure. For example, the touch panel 1610 may be disposed on the display panel 1710.

The touch panel 1610 and the display panel 1710 may have a single layer structure. For example, the touch panel 1610 and the display panel 1710 may be disposed on one board.

Although specific embodiments are described in the detailed description of the inventive concept, the detailed description may be amended or modified without being out of the scope of the inventive concept.

What is claimed is:

1. A touch sensing apparatus comprising:
a touch panel; and
a touch sensor configured to control the touch panel and sense a touch event occurring on the touch panel,
wherein the touch sensor comprises a plurality of sensing units, each of sensing unit is connected to the touch panel through a plurality of sensing lines respectively, and
wherein each of the plurality of sensing units comprises at least an operational amplifier whose polarity varies in response to a clock signal.

2. The touch sensing apparatus of claim 1, wherein the operational amplifier comprises:
a differential input unit configured to detect a value of a signal level at a first input node minus a signal level at a second input node in response to a first edge of the clock signal to output a first detection signal, and detect a value of the signal level at the second input node minus the signal level at the first input node in response to a second edge of the clock signal to output a second detection signal;
an amplification unit configured to amplify the first detection signal in response to the first edge of the clock signal to output a first amplification signal and amplify the second detection signal in response to the second edge of the clock signal to output a second amplification signal; and
an output unit configured to output the first amplification signal in response to the first edge of the clock signal and output the second amplification signal in response to the second edge of the clock signal.

3. The touch sensing apparatus of claim 2, wherein each of the plurality of sensing units comprises:
a charge amplifier configured to convert a current signal received through one of the plurality of sensing lines into a voltage signal to output the converted voltage signal;
a demodulator configured to demodulate the output signal of the charge amplifier;
a low pass filter configured to filter the output signal of the demodulator;
a gain amplifier configured to amplify the output signal of the low pass filter; and
an analog-to-digital converter configured to sample the output signal of the gain amplifier in response to a sampling clock signal,
wherein the operational amplifier is disposed in at least one of the demodulator, the low pass filter, and the gain amplifier.

4. The touch sensing apparatus of claim 3, wherein the demodulator comprises:
a first operational amplifier configured to operate in response to a first clock signal and forming a voltage follower configured to transmit the output signal of the charge amplifier;
a second operational amplifier configured to operate in response to a second clock signal and forming an inverter configured to invert the output signal of the charge amplifier to output the inverted signal; and
a multiplexer configured to select one of the outputs of the first operational amplifier and of the second operational amplifier in response to a demodulating clock signal to output the selected output.

5. The touch sensing apparatus of claim 4, wherein the touch sensor further comprises a driving circuit connected to the touch panel through a plurality of driving lines, and
wherein the driving circuit is configured to output a pulse signal comprising a series of pulses to each of the plurality of driving lines.

6. The touch sensing apparatus of claim 5, wherein the demodulating clock signal has a same period and duty ratio as the pulse signal.

7. The touch sensing apparatus of claim 4, wherein the duty ratios of the first clock signal and the second clock signal are substantially same as the duty ratio of the demodulating clock signal; and the periods and pulse widths of the first clock signals and the second clock signal are substantially twice as great as the demodulating clock signal; wherein the first clock signal and the second clock signal are synchronized with the demodulating clock signal.

8. The touch sensing apparatus of claim 4, wherein the demodulating clock signal has the first edge when the first clock signal is maintained at a predetermined level without being transited and the second edge when the second clock signal is maintained at a predetermined level without being transited.

9. The touch sensing apparatus of claim 4, wherein the demodulating clock signal is at the first edge when a first time elapses after the first clock signal is transited and the demodulating clock signal is at the second edge when a second time elapses after the second clock signal is transited.

10. The touch sensing apparatus of claim 3, wherein the low pass filter further comprises:
a first low pass filter configured to filter the output signal of the multiplexer; wherein the first low pass filter comprises a third operational amplifier configured to operate in response to a third clock signal; and
a second low pass filter configured to filter the output signal of the first low pass filter; wherein the second low pass filter comprises a fourth operational amplifier configured to operate in response to a fourth clock signal.

11. The touch sensing apparatus of claim 10, wherein the fourth clock signal is synchronized with the sampling clock signal.

12. The touch sensing apparatus of claim 10, wherein the analog-to-digital converter is configured to perform the sampling when a predetermined time elapses after the fourth clock signal is transited.

13. The touch sensing apparatus of claim 3, wherein the gain amplifier comprises:
a fifth operational amplifier;
an input resistor; and
an feedback resistor;
wherein the gain amplifier configured to amplify the output signal of the low pass filter according to a resistance ratio of the input resistor to the feedback resistor and operate in response to a fifth clock signal, wherein the analog-to-digital converter is configured to perform the sampling when a predetermined time elapses after the fifth clock signal is transited.

14. The touch sensing apparatus of claim 3, wherein the charge amplifier comprises an operational amplifier connected to one of the plurality of sensing lines; a feedback resistor; and a feedback capacitor,
wherein each of the plurality of sensing units further comprises a saturation detector configured to detect whether the charge amplifier is saturated to output a saturation flag signal.

15. The touch sensing apparatus of claim 14, wherein each of the plurality of sensing units further comprises a capacitance controller configured to adjust a capacitance of the feedback capacitor in response to the saturation flag signal.

16. The touch sensing apparatus of claim 14, further comprising a capacitance controller configured to adjust capacitances of feedback capacitors of the charge amplifiers of the plurality of sensing units in response to the saturation flag signal.

17. The touch sensing apparatus of claim 14, wherein each of the plurality of sensing units further comprises a noise detector configured to detect a noise from the output signal of the charge amplifier to output a noise flag signal.

18. The touch sensing apparatus of claim 17, wherein a capacitance of the feedback capacitor of the charge amplifier is adjusted in response to the saturation flag signal and the noise flag signal.

19. An operational amplifier comprising:
a differential input unit configured to detect a value of a signal level at a first input node minus a signal level at a second input node in response to a first edge of a clock signal to output a first detection signal, and detect a value of the signal level at the second input node minus the signal level at the first input node in response to a second edge of the clock signal to output a second detection signal;
an amplification unit configured to amplify the first detection signal in response to the first edge of the clock signal to output a first amplification signal and amplify the second detection signal in response to the second edge of the clock signal to output a second amplification signal; and
an output unit configured to output the first amplification signal in response to the first edge of the clock signal and output the second amplification signal in response to the second edge of the clock signal.

20. A touch sensing apparatus comprising:
a touch panel; and
a touch sensor configured to control the touch panel and sense a touch event occurring on the touch panel,
wherein the touch sensor comprises a plurality of sensing units, each sensing unit is connected to the touch panel through a plurality of sensing lines respectively;
wherein each of the plurality of sensing units comprises:
a charge amplifier configured to convert a current signal received through a sensing line into a voltage signal to output the converted voltage signal;
a demodulator configured to demodulate the output signal of the charge amplifier;
a low pass filter configured to filter the output signal of the modulator;
a gain amplifier configured to amplify the output signal of the low pass filter;
an analog-to-digital converter configured to sample the output signal of the gain amplifier in response to a sampling clock signal;
a saturation detector configured to receive the output signal of the charge amplifier and detect whether the charge amplifier is saturated to output a saturation flag signal; and
a controller configured to adjust an amplification factor of the charge amplifier in response to the saturation flag signal.

21. The touch sensing apparatus of claim 20, wherein the controller includes a capacitance controller configured to adjust a capacitance of the feedback capacitor in the charge amplifier.

22. The touch sensing apparatus of claim 20, wherein the charge amplifier further comprises:
an operational amplifier configured to receive the output signal received through one of the plurality of sensing lines; and
a noise detector configured to receive the output signal of the charge amplifier and detect a noise from the output signal of the charge amplifier to output a noise flag signal.

23. A touch sensor for controlling a touch panel comprising:
a driving circuit configured to output a pulse signal to each of a plurality of driving lines connected to the touch panel;
a sensing circuit configured to sense a signal received from a plurality of sensing lines connected to the touch panel; and
a control and processing circuit configured to control the driving circuit and the sensing circuit, and determine whether a touch event has occurred on the touch panel,
wherein the sensing circuit comprises a plurality of sensing units connected to the touch panel through a plurality of sensing lines, respectively,
wherein each of the plurality of sensing unit comprises a charge amplifier configured to convert a current signal received through each of the plurality of sensing lines into a voltage signal to output the converted voltage signal, and
wherein a capacitance of the feedback capacitor in the charge amplifier is adjusted by a capacitance controller.

24. The touch sensor of claim 23, the capacitance controller is located either in the sensing circuit or in the control and processing unit.

25. The touch sensor of claim 23, further comprising a saturation detector configured to receive the output signal of the charge amplifier and detect whether the charge amplifier is saturated.
